(19) United States
(12) Patent Application Publication
(10) Pub. No.: US 2009/0033346 A1
(43) Pub. Date: Feb. 5, 2009

(54) GROUP PROBING OVER ACTIVE AREA PADS ARRANGEMENT

(76) Inventors: Ping-Chang Wu, Hsin-Chu Hsien (TW); Chieh-Ching Huang, Miaoli County (TW)

Correspondence Address: NORTH AMERICA INTELLECTUAL PROPERTY CORPORATION, P.O. BOX 506, MERRIFIELD, VA, 22116, US

(21) Appl. No.: 11/830,833

(22) Filed: Jul. 30, 2007

(51) Int. Cl. G01R 1/073

(52) U.S. Cl. 324/754

(57) ABSTRACT

A group probing over active area (POAA) pads arrangement includes a chip having a set of bonding pads, at least a first set of probing pads and a second set of probing pads. Each of the first set of probing pads and the second set of probing pads are electrically connected to one of the corresponding bonding pads, respectively. And each of the first set of probing pads and the second set of probing pads are interlaced in a diagonal line pattern. According to a concept of grouping and interlacing the probing pads, each bonding pad obtains at least two probing pads. Therefore times of test probing performed on each probing pad are reduced and repeated probe's pressures toward inter metal dielectric (IMD) layers underneath the probing pads are consequently reduced.

### BACKGROUND OF THE INVENTION

1. Field of the Invention

This invention relates to a group probing over active area (POAA) pads arrangement, and more particularly, to a group POAA pads arrangement for multi-probe.

2. Description of the Prior Art

In the semiconductor industry, an integrated circuit (IC) product is obtained by sequentially undergoing IC design, semiconductor processes, and fabrication of the IC etc. After completing those procedures, multi-probe processes are performed by contacting bonding pads with testing probes or a probing card. Only the chips qualified in the test probing or repaired chips would enter into following bonding and packaging processes, and still the packaged chips need a final testing for qualifying.

As mentioned above, test probing is performed by contacting the bonding pads with the probing card, thus an electrical testing for the bonding pads and its internal circuits is carried out. For improving and assuring performance of the whole system, test probing is performed many times. Additionally, for assuring that the testing probe contacts the bonding pads accurately, the contact motion would be carried out many times. Therefore probing marks or dents are often formed on surfaces of the bonding pads, even rendering destructive damages. Since the boding pads not only serve as where the test probing is performed, but also serve as terminals between the chip and other devices, said damaged bonding pads adversely influence following bumping or wire bonding processes and reduce reliability and yield. In another circumstance, when a final testing process is performed at solder bumps or wire bonds after packaging, the tips of the testing probes may also cause probing marks or dents on the solder bumps or wire bonds and consequently reduce reliability and yield.

Therefore solutions for the above mentioned problems are provided. Please refer to FIG. 1, which is a schematic drawing illustrating a conventional package structure with POAA pads. As shown in FIG. 1, a package structure comprises a chip 100, a plurality of bonding pads 102 positioned on the chip 100, and a protecting layer 104 formed on the bonding pads 102. The protecting layer 104 has two openings, one of the openings exposes a portion of the bonding pad for forming a solder bump 106; another opening exposes another portion of the bonding pads 102 for serving as a single probing pads 108. In another approach, as shown in FIG. 2, which is another schematic drawing illustrating a package structure with POAA pads, a redistributed layer (RDL) 112 is provided and the bonding pad 102 and the single probing pad 108 are formed thereon. According to the conventional POAA, what contacts with the testing probe in the test probing is the single probing pad 108 corresponding to the bonding pad 102. And the bonding pad 102 or the solder bump 108 which possess practical function of electrical connection is protected from damages caused by the testing probe in the test probing.

As mentioned above, to assure the performance of the whole system, the multi-probe is applied to the probing pads 108 many times. Therefore the single probing pad 108 is getting insufficient in products need more complicated and more test probing such as system-on-chip (SOC). Additionally, in recent years, the semiconductor process of deep sub-micro advances to high integration below 0.18 μm with an inter metal dielectric (IMD) layer collocated by the dual damascene technology. And usage of low dielectric (low-K) material, ultra low-k (ULK) material, or porous low-k material has been the most popular metal interconnects technology to date. However, the low-k, ULK, or porous low-k materials are fragile, therefore said IMD layer underneath the bonding pads and its corresponding probing pads may collapse or wreck after being probed many times by the multi-probe, and thus performance of the whole system is adversely influenced.

Therefore, an arrangement of probing pads capable of withstanding the multi-probe and reducing probe's pressures toward the IMD layer underneath the probing pads is needed.

### SUMMARY OF THE INVENTION

Therefore a group probing over active area (POAA) pad arrangement capable of withstanding the multi-probe and reducing the probe's pressure toward the IMD layer underneath the POAA pads is provided by the present invention.

According to the claimed invention, a group probing over active area (POAA) pads arrangement is provided. The group POAA pads arrangement comprises a chip having a set of bonding pads, at least a first set of probing pads, and a second set of probing pads, each of the first set of probing pads and the second set of probing pads are electrically connected to one of the corresponding bonding pads respectively and interlaced in a diagonal line pattern.

According to the claimed invention, another group probing over active area (POAA) pads arrangement is provided. The group POAA pads arrangement comprises a chip having a set of bonding pads, at least a first set of probing pads, and a second set of probing pads, each of the first set of probing pads and the second set of probing pads are electrically connected to one of the bonding pads respectively and are horizontally or perpendicularly interlaced.

The probing pads provided by the present invention are arranged into the first set of probing pads and the second set of probing pads by a concept of grouping. And the first set of probing pads and the second set of probing pads are horizontally or perpendicularly interlaced, or interlaced in a diagonal line pattern. According to the group POAA pads arrangement, each of the bonding pads obtains at least two corresponding probing pads for the test probing. Therefore times of the test probing performed on each of the first set of probing pads and the second set of probing pads are reduced and probe's pressures toward inter metal dielectric (IMD) layers underneath the first set of probing pads and the second set of probing pads are consequently reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 and 2 are schematic drawings illustrating conventional package structures with POAA pads.

FIG. 3 is a schematic drawing illustrating a first preferred embodiment provided by the present invention.

FIG. 4 is an enlarged view of a portion of the group POAA pads arrangement shown in FIG. 3.

FIGS. 5-6 are enlarged views of a portion of the group POAA pads arrangement according to second preferred embodiments provided by the present invention.

FIGS. 7 and 8 are cross-sectional views of the group POAA pads arrangement along the dashed line 208 shown in FIG. 4.

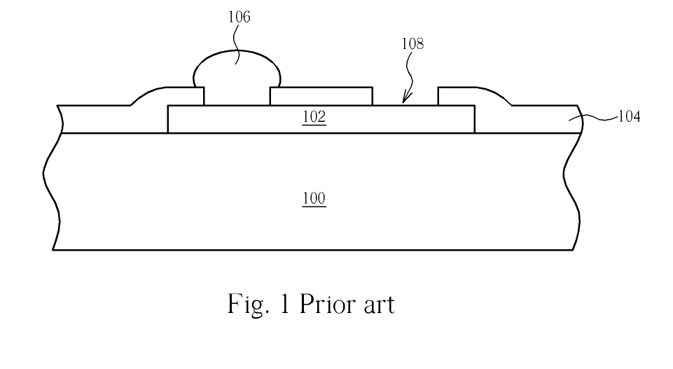

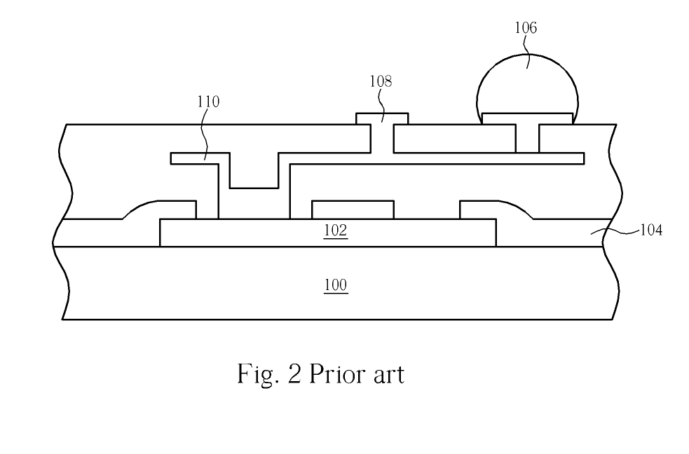

### DETAILED DESCRIPTION

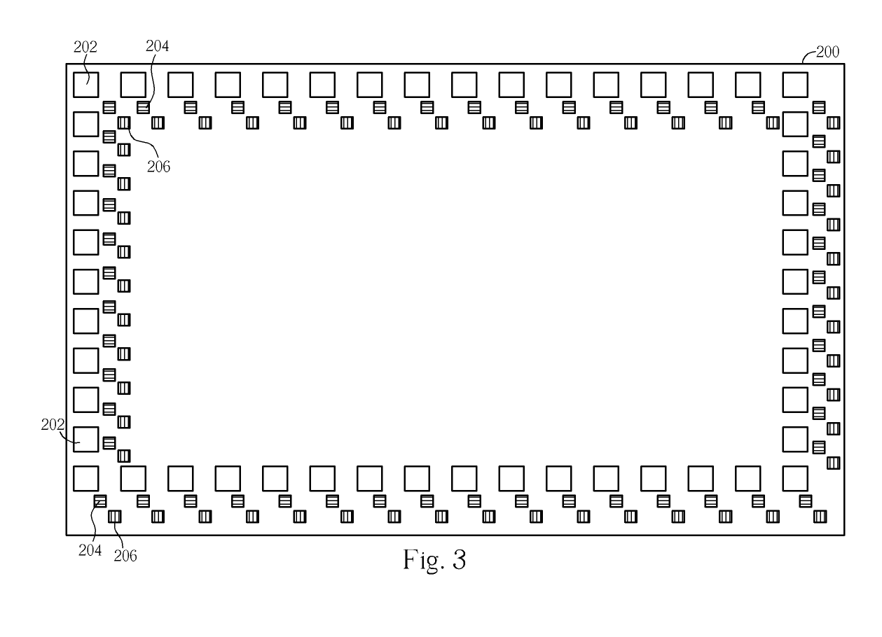

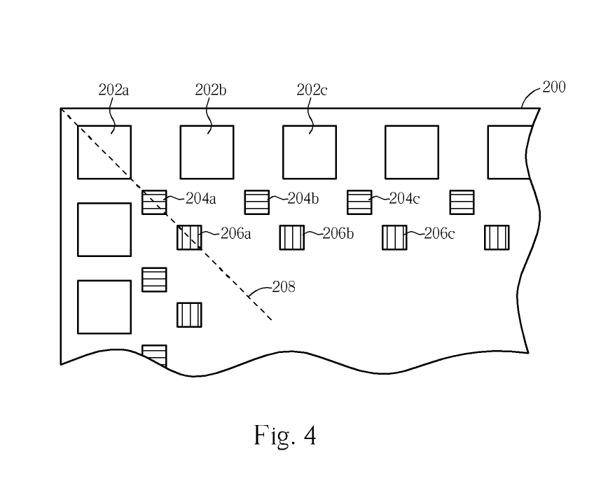

Please refer to FIGS. 3-4, FIG. 3 is a schematic drawing illustrating a first preferred embodiment provided by the present invention; and FIG. 4 is an enlarged view of a portion of the group POAA pads arrangement in FIG. 3. As shown in FIG. 3, the group POAA pads arrangement provided by the present invention comprises a chip 200, and the chip 200 has a set of bonding pads 202, at least a first set of probing pads 204, and a second set of probing pads 206. The bonding pads provide external electrical connections by wire bonding or bumping. Each of the first set of probing pads 204 and the second set of probing pads 206 are electrically connected to one of the corresponding bonding pads 202, respectively. As shown in FIG. 4, the first set of probing pads 204a and the second set of probing pads 206a are electrically connected to the bond pad 202a, and the first set of probing pads 204b and the second set of probing pads 206b are electrically connected to the bond pad 202b, and so on. Furthermore, the first set of probing pads 204 and the second set of probing pads 206 are interlaced in a diagonal line pattern. Please refer to FIG. 4 again, the first set of probing pads 204a and the second set of probing pads 206a, together with the bonding pad 202a are interlaced in a diagonal line pattern. However, such diagonal line arrangement is limited to the bonding pad 202a as shown in FIG. 4. In other words, bonding pad 202 is not necessarily positioned in the diagonal line pattern with the first set of probing pads 204 and the second set of probing pads 206.

As shown in FIG. 4, relative positions between each of the first set of probing pads 204a, 204b, and 204c, etc. and relative positions between each of the second set of probing pads 206a, 206b, and 206c, etc are identical. Said relative positions are also similar with relative positions of testing probes of a probing card. According to the group POAA pads arrangement, the first set of probing pads 204 and the second set of probing pads 206 provide occupations for test probing of identical or different functions with one probe card.

It is noteworthy that since the test probing is carried out many times in stages of the semiconductor processes and the testing probes have to contact the probing pads many times for assuring accurate contact, probing marks or dents are often left on surfaces of the probing pads. According to the present invention, when the first set of probing pads 204 has undergone several times of test probing with consideration of preventing the IMD layers underneath the first set of probing pads 204 from damage, the probe card is shifted one pitch to the second set of probing pads 206 for continuing test probing. Therefore times of test probing carried out on each of the probing pads are reduced and the repeated probe's pressures toward the IMD layers underneath the probing pads are consequently reduced.

Additionally, with progress of semiconductor processes, deep sub-micro with high integration below 0.18 μm utilizing inter metal dielectric (IMD) layer collocated by the dual damascene technology and usage of low dielectric (low-K) material, ultra low-k (ULK) material, or porous low-k material, which is fragile, is the most popular metal interconnects technology to date. Please note that according to the present invention, repeated probe's pressure toward the IMD layers of said dielectric material is reduced when times of test probing carried out on each of the probing pads are reduced. Therefore collapse or wreck of the IMD layer is efficiently prevented. Additionally, since times of the test probing increase with the progress of the semiconductor fabricating process, other sets of probing pads can be positioned and interlaced on the chip in diagonal pattern according to the group POAA pads arrangement provided by present invention. Thus more testing space is obtained.

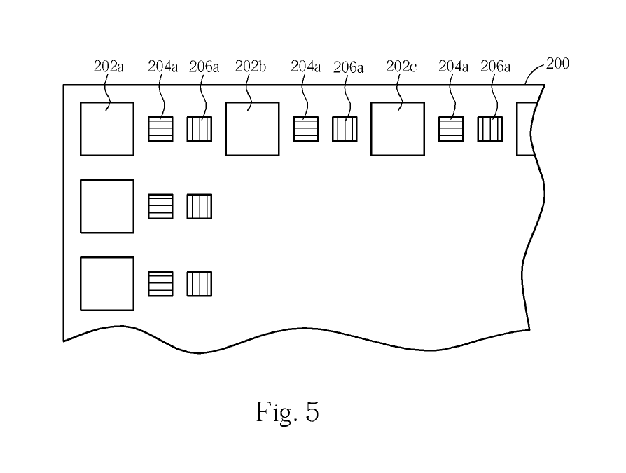

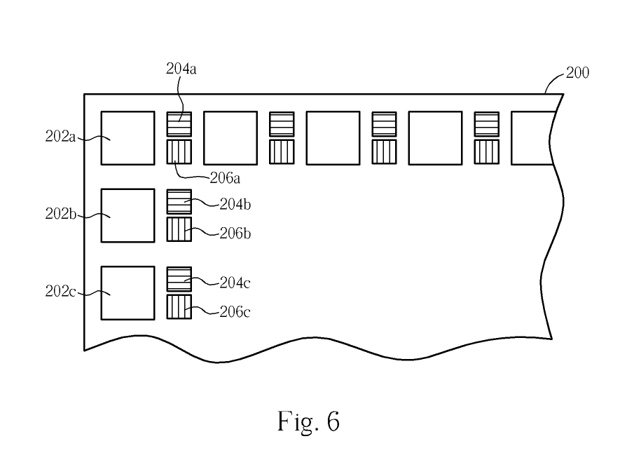

Please refer to FIGS. 5-6, which are enlarged views of a portion of the group POAA pads arrangement according to a second preferred embodiments provided by the present invention. As shown in FIGS. 5-6, the group POAA pads arrangement provided by the present invention comprises a chip 200, the chip 200 has a set of bonding pads 202, at least a first set of probing pads 204, and a second set of probing pads 206. The bonding pads provide external electrical connections by wire bonding or bumping. Each of the first set of probing pads 204 and the second set of probing pads 206 are electrically connected to one of the corresponding bonding pads 202 respectively. For instance, the first set of probing pads 204a and the second set of probing pads 206a are electrically connected to the bond pad 202a, the first set of probing pads 204b and the second set of probing pads 206b are electrically connected to the bond pad 202b, and so on. Furthermore, as shown in FIG. 5, the first set of probing pads 204 and the second set of probing pads 206 are horizontally interlaced; and shown in FIG. 6, the first set of probing pads 204 and the second set of probing pads 206 are perpendicularly interlaced.

Please refer to FIGS. 5-6 again. Relative positions between each of the first set of probing pads 204a, 204b, and 204c, etc. and relative positions between each of the second set of probing pads 206a, 206b, and 206c, etc. are identical. Said relative positions are also similar with relative positions of testing probes of a probing card. According to the group POAA pads arrangement provided by the present invention, the first set of probing pads 204 and the second set of probing pads 206 provide occupations for test probing of identical or different functions with one probe card.

It is noteworthy that since the test probing is carried out many times in stages of the semiconductor processes and the testing probes have to contact the probing pads repeatedly for assuring accurate contact, probing marks or dents are often left on surfaces of the probing pads. According to the present invention, when the first set of probing pads 204 has undergone several times of test probing with consideration of preventing the IMD layers underneath the first set of probing pads 204 from damage, the probe card is shifted one pitch to the second set of probing pads 206 for continuing test probing. Therefore times of test probing carried out on each of the probing pads are reduced and the repeated probe's pressures toward the IMD layers underneath the probing pads are consequently reduced. Additionally, since times of the test probing increase with the progress of the semiconductor fabricating process, other sets of probing pads can be horizontally or perpendicularly interlaced and positioned on the chip according to the group POAA pads arrangement provided by present invention. Thus more testing space is obtained.

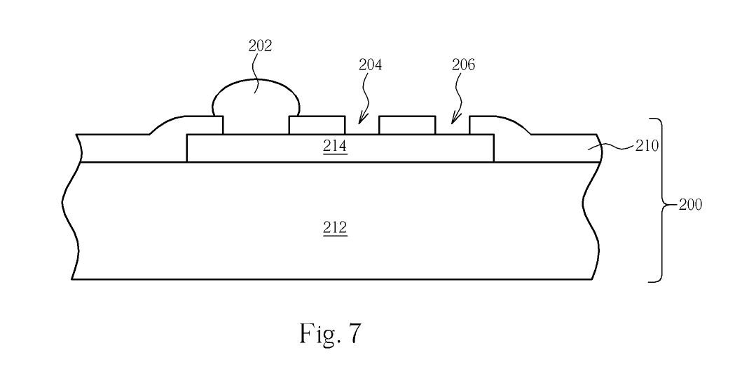

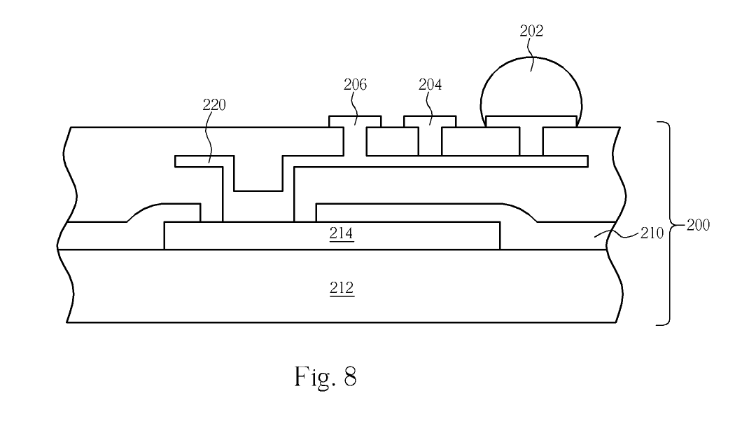

Please refer to FIGS. 7-8, which are cross-sectional views of the group POAA pads arrangement along the dashed line 208 shown in FIG. 4. As shown in FIG. 7, a chip 200 comprises a set of bonding pads 202 for providing external electrical connection. In this embodiment, the electrical connection is provided by bumping. The chip 200 also comprises a first set of probing pads 202 and a second set of probing pads 204 providing occupations for test probing. The first set of probing pads 204 and the second set of probing pads 206 are exposed in a protecting layer 210. Please note that a plurality of IMD layers made of fragile low-K, ULK, or porous low-K material are formed underneath the bonding pads 202, the first set of probing pads 204, and the second set of probing pads 206. According to the group POAA pads arrangement provided by the present invention, times of test probing carried out on each of the probing pads are reduced and the repeated probe's pressures toward the IMD layers underneath the probing pads are consequently reduced. Therefore collapse or wreck of the IMD layer is efficiently prevented.

Furthermore, as shown in FIG. 8, the bonding pads 202, the fist set of probing pads 204, and the second set of probing pads 206 are electrically connected by a redistributed layer (RDL) 220. The RDL 220 is utilized to adjust positions of the bonding pads 202, the fist set of probing pads 204, and the second set of probing pads 206, thus stability of those elements are further improved. It is noteworthy that, as shown in FIGS. 7-8, the first set of probing pads 204 and the second probing pads 206 are probing pads formed on a metal pad 210 by being exposed in the protecting layer 210, and such arrangement would not consume valuable space of the chip 200.

As mentioned above, the probing pads provided by the present invention are arranged into the first set of probing pads and the second set of probing pads by a concept of grouping. And the first set of probing pads and the second set of probing pads are horizontally or perpendicularly interlaced, or interlaced in a diagonal line pattern. According to the present invention, each of the bonding pads obtains at least two corresponding probing pads for the test probing. Therefore times of the test probing performed on each of the first set of probing pads and the second set of probing pads is reduced and repeated probe's pressures toward inter metal dielectric (IMD) layers underneath the first set of probing pads and the second set of probing pads are consequently reduced.

Those skilled in the art will readily observe that numerous modifications and alterations of the device and method may be made while retaining the teachings of the invention.

What is claimed is:

1. A group probing over active area (POAA) pads arrangement comprising:
a chip having a set of bonding pads, at least a first set of probing pads, and a second set of probing pads, each of the first set of probing pads and the second set of probing pads being electrically connected to one of the corresponding bonding pads respectively and interlaced in a diagonal line pattern.

2. The group POAA pads arrangement of claim 1, wherein the bonding pads provide external electrical connections.

3. The group POAA pads arrangement of claim 1, wherein the electrical connection is provided by wire bonding or bumping.

4. The group POAA pads arrangement of claim 1 further comprising at least a conductive line providing an electrical connection between the bonding pad, the first set of probing pads, and the second set of probing pads.

5. The group POAA pads arrangement of claim 1, wherein relative positions between each of the first set of probing pads and relative positions between each of the second set of probing pads are identical.

6. The group POAA pads arrangement of claim 1, wherein the first set of probing pads and the second set of probing pads provide occupations for test probing.

7. The group POAA pads arrangement of claim 6, wherein the test probing is performed by contacting the first set of probing pads and the second set of probing pads with a same probe card.

8. The group POAA pads arrangement of claim 1, wherein the first set of probing pads and the second set of probing pads are positioned for test probing of different functions.

9. A group probing over active area (POAA) pads arrangement comprising:
a chip having a set of bonding pads, at least a first set of probing pads, and a second set of probing pads, each of the first set of probing pads and the second set of probing pads being electrically connected to one of the corresponding bonding pads respectively and being horizontally or perpendicularly interlaced.

10. The group POAA pads arrangement of claim 9, wherein the bonding pads provide external electrical connections.

11. The group POAA pads arrangement of claim 10, wherein the electrical connection is provided by wire bonding or bumping.

12. The group POAA pads arrangement of claim 9 further comprising at least a conductive line providing an electrical connection between the bonding pad, the first set of probing pads, and the second set of probing pads.

13. The group POAA pads arrangement of claim 9, wherein relative positions between each of the first set of probing pads and relative positions between each of the second set of probing pads are identical.

14. The group POAA pads arrangement of claim 9, wherein the first set of probing pads and the second set of probing pads providing occupations for test probing.

15. The group POAA pads arrangement of claim 14, wherein the test probing is performed by contacting the first set of probing pads and the second set of probing pads with a same probe card.

16. The group POAA pads arrangement of claim 9, wherein the first set of probing pads and the second set of probing pads are positioned for test probing of different functions.
